(19) United States
(12) Patent Application Publication
(10) Pub. No.: US 2020/0144186 A1
(43) Pub. Date: May 7, 2020

(54) ACTIVE SILICON BRIDGE

(71) Applicant: Intel Corporation, Santa Clara, CA (US)

(72) Inventors: Thomas P. THOMAS, Portland, OR (US); Wilfred GOMES, Portland, OR (US); Ravindranath V. MAHAJAN, Chandler, AZ (US); Rajesh KUMAR, Portland, OR (US); Mark T. BOHR, Aloha, OR (US); Dheeraj SUBBAREDDY, Portland, OR (US); Ankireddy NALAMALPU, Portland, OR (US); Mahesh KUMASHIKAR, Bangalore (IN)

(21) Appl. No.: 16/632,714

(22) PCT Filed: Sep. 13, 2017
(86) PCT No.: PCT/US2017/051320

§ 371 Date: Jan. 21, 2020

(51) Int. Cl. H01L 23/538; H01L 25/065; H01L 23/00; H01L 21/50

(52) U.S. Cl. CPC H01L 23/5381; H01L 25/0652; H01L 21/50; H01L 23/5386; H01L 24/95; H01L 23/5385

(57) ABSTRACT

A package substrate and a package assembly including a package substrate including a substrate body including a plurality of first contact points on a surface thereof configured for electrical connection to a first die and a plurality of second contact points on the surface configured for electrical connection to a second die; and a bridge coupled to the substrate body, the bridge including active device circuitry that is coupled to ones of the plurality of first contact points and ones of the plurality of second contact points. A method of forming a package assembly including coupling a first die to a package substrate, the package substrate including a bridge substrate including active device circuitry; and coupling a second die to the package substrate, wherein coupling the first die and the second die to the package substrate includes coupling the first die and the second die to the active circuitry.

### FIELD

Integrated circuits, and more particularly, to package assemblies.

### BACKGROUND

Integrated circuit (IC) product architecture often incorporates a number of heterogeneous functions such as central processing unit (CPU) logic, graphics functions, cache memory and other system functions to create integrated system-on-chip (SOC) designs, which may lower product design complexity and number of components for each product. Previously, products may have required that an end customer design a system board using separate packages for the different functions, which may increase a system board area, power loss, and, thus, cost of an integrated solution.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a cross-section side view of an embodiment of an integrated circuit (IC) package assembly including an embedded active bridge.

FIG. 2 schematically illustrates a cross-section of another embodiment of a portion of a package assembly including a package substrate including an embedded active bridge therein, the bridge containing repeaters in signal paths through the bridge.

FIG. 3 schematically illustrates a cross-sectional side view of another embodiment of a package assembly including an active bridge embedded in a package substrate and including a memory controller and optionally other protocols and a microprocessor (e.g., CPU) and memory die(s) connected to the package substrate and electrically connected to the bridge.

FIG. 4 schematically illustrates another embodiment of a package assembly including an active bridge embedded in a package substrate and a microprocessor (e.g., CPU) and memory die(s) connected to the package substrate and to the bridge.

FIG. 5 shows a high level architecture for a controller and physical interface for memory devices incorporated into a package assembly.

FIG. 6 illustrates an embodiment of a computing device.

### DETAILED DESCRIPTION

Embodiments of the disclosure describe techniques and configurations for a package assembly including, but not limited to a package substrate including at least one embedded bridge.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the disclosure, the phrase “A and/or B” means (A), (B), or (A and B). For the purposes of the disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “module” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

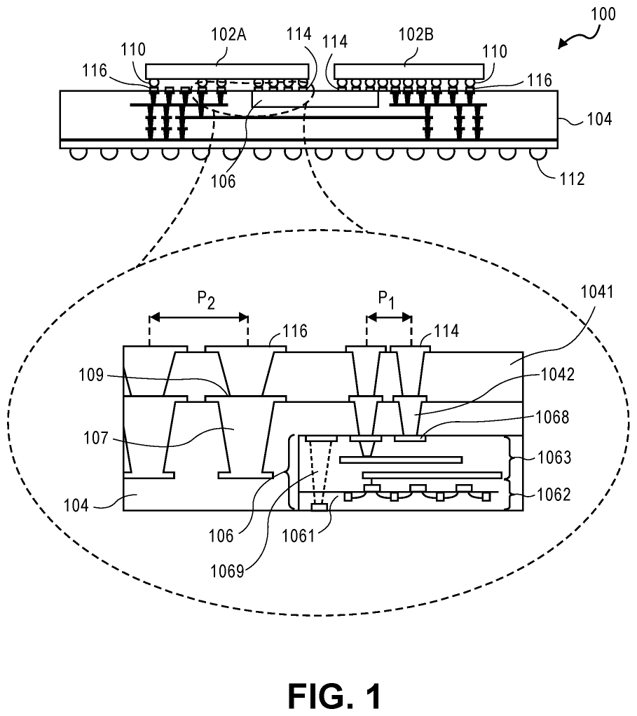

FIG. 1 schematically illustrates a cross-section side view of an embodiment of an integrated circuit (IC) package assembly 100 including embedded bridge interconnect assembly 106 (hereinafter “bridge 106”). In this embodiment, package assembly 100 includes package substrate 104 having a plurality of (e.g., two or more) dies (die 102A and die 102B shown) mounted on a surface of package substrate 104 (a top surface as viewed). Package substrate 104, in one embodiment, includes an epoxy-based laminate substrate or body having a core and/or build-up layers such as, for example, an Ajinomoto Build-up Film (ABF) substrate. Package substrate 104 may include other suitable types of substrates in other embodiments.

Dies 102A and 102B may be, include, or be a part of a processor, memory, or application specific integrated circuit (ASIC) in some embodiments. Each of dies 102A and 102B may represent a discrete chip. Dies 102A and 102B can be attached to package substrate 104 according to a variety of suitable configurations including, a flip-chip configuration, as depicted, or other configurations such as wirebonding and the like. In the flip-chip configuration, an active or device side of dies 102A and 102B is attached to a surface of package substrate 104 (a top surface as viewed) using die interconnect structures 110 such as bumps or pillars.

In one embodiment, bridge 106 is embedded in a body of package substrate 104. Bridge 106 includes active device circuitry formed therein or thereon. Active device circuitry, in one embodiment, includes at least one active device that is a three terminal device where at least one of the terminals of the device can be used to control a behavior of the device (e.g., control electron flow). A transistor is one example of an active device. Thus, in one embodiment, bridge 106 includes a plurality of transistors that are configured to perform one or more functions. Examples include circuit functions such as, but not limited to, repeaters in input/output (I/O) signal paths, memory functions (e.g., read only memory (ROM)), controllers (e.g., memory controllers), drivers and test functions (e.g., lane fail-over, scan). In one embodiment, bridge 106 includes a bridge substrate or body of a semiconductor material such as single crystal silicon. Disposed in and/or on a surface of the bridge substrate or body is a device level including a plurality of transistor devices. Such transistor devices may be connected as desired for particular circuit functions by metallization (conductive vias and one or more metal lines or layers) connected to the device level. A surface of bridge 106 (a top surface as viewed) includes electrical routing features connected to devices or circuits of bridge 106. The routing features are electrically connected to dies 102A and 102B in a face-to-face (device side-to-device side) connection through ones of die interconnect structures 110. Die interconnect structures 110 may be configured to route electrical signals between dies 102A and 102B and package substrate 104. In some embodiments, die interconnect structures 110 may be configured to route electrical signals such as, for example, input/output (I/O) signals, power and/or ground signals associated with the operation of dies 102A and 102B.

Package substrate 104 includes electrical routing features configured to route electrical signals to or from the dies 102A and 102B. The electrical routing features may be internal and/or external to the bridge 106. In one embodiment, package substrate 104 includes electrical routing features such as external contact points (e.g., pads) configured to receive die interconnect structures 110 and route electrical signals to or from dies 102A. FIG. 1 shows contact points 114 and contact points 116. Contact points 114 are associated with bridge 106 (e.g., vias and traces to or from bridge 106 are connected to contact points 114). In one embodiment, contact points 114 are configured to route input/output (I/O) signals and/or other signals between dies 102A and 102B and bridge 106. In another embodiment, contact points are also used to route power and ground signals between dies 102A and 102B and bridge 106. Contact points 116 are associated with the body of package substrate 104 (e.g., vias and traces that run through the body of package substrate 104). In one embodiment, contact points 116 are configured to route power and ground and other signals between package substrate 104 and dies 102A and 102B. Package substrate 104 further includes package level interconnects 112 such as, for example, solder balls, connected to a surface of the package substrate 104 (a backside surface as viewed) to further route electrical signals to other electrical devices (e.g., motherboard or other chipset).

Dies 102A and 102B are electrically connected to bridge 106 through an electrically conductive connection between ones of die interconnect structures 110 and contact points 114 and contact points 116. In one embodiment, bridge 106 is configured to route electrical signals between the dies 102A and 102B. In one embodiment, bridge 106 is embedded in a cavity of package substrate 104. In some embodiments, a portion of dies 102A and 102B may overly the embedded bridge 106. In another embodiment, bridge 106 may be connected to a surface of package substrate 104 similar to dies 102A and 102B.

Although two dies (dies 102A and 102B) and one bridge 106 are depicted in connection with FIG. 1, other embodiments may include more or fewer dies and bridges connected together in other possible configurations including three-dimensional configurations. For example, another die that is disposed on package substrate 104 in or out of the page relative to dies 102A and 102B of FIG. 1 may be connected to dies 102A and 102B using bridge 106 or another bridge.

An inset of FIG. 1 shows a magnified view of a portion of package substrate 104. Package substrate 104 includes a substrate body including surface layer 1041 defining a superior surface of the substrate body. Surface layer 1041, in one embodiment, is a dielectric material such as solder resist or other photoimageable dielectric material. The inset shows bridge 106 embedded in the substrate body of package substrate 104. Bridge 106 includes bridge substrate 1061, which may be composed of a high resistivity/low conductivity material such as, for example, a semiconductor material such as silicon. Disposed on and/or in a surface of substrate 1061 is device layer 1062 including a plurality of transistor devices and optionally other devices (e.g., capacitors). Transistor devices may be planar devices or non-planar devices (e.g., multi-gate devices) formed according to fabrication techniques known in the art. A backside of substrate 1061 may be connected to package substrate 104 through an adhesive. Overlying device layer 1062 is metallization layer(s) 1063. Metallization layer(s) 1063 includes conductive vias and one or more metal lines connected to ones of the plurality of devices in device layer 1062. Metallization layer 1063 may also include one or more routing layers (metal layers) that are not connected to device layer 1062 but are used to directly route signals through bridge 106 (passive signal lines). One or more electrical routing features may optionally be formed on and through bridge 106 to provide an electrical pathway between opposing surfaces (top and bottom surfaces as viewed) of bridge 106. In an embodiment where the bridge substrate 1061 is composed of silicon, the one or more optional may be through silicon vias (TSVs) 1069.

Bridge 106 includes electrical routing features such as, for example, pads or traces and the like (referred to generally as “bridge surface routing features 1068”) that may be formed on a surface of bridge 106 (a top surface as viewed) to route electrical signals between dies (e.g., dies 102A and 102B) on package substrate 104. For example, bridge surface routing features 1068 may be electrically connected with package routing features formed in package substrate 104 such as, for example, vias 1042 or other routing structure. The package routing features (e.g., vias 1042), in one embodiment, are configured to be electrically connected with the dies (e.g., dies 102A and 102B). Where TSVs 1069 are present in bridge 106, bridge surface routing features 1068 may also be present on a bottom surface of bridge 106 to electrically connect the bridge to electrically connect the bridge to package substrate 104.

Referring to the inset of FIG. 1, package substrate 104 includes contact points 114.

In one embodiment, contact points 114 are conductive vias or pillars of an electrically conductive material (e.g., copper) having a base connected to ones of vias 1042 and a top or superior surface available for an electrically conductive connection with die interconnect structures 110 of dies 102A and 102B. In one embodiment, contact points 114 are a copper material formed by electroplating a conductive material in openings formed through surface layer 1041 (e.g., openings formed by laser drilling or lithographic means. In one embodiment, contact points 114 of package substrate 104 have a pitch, P₁, that is on the order of 50 microns (μm) or less (e.g., 30 μm). Generally speaking, in one aspect, a density of contact points 114 dictates a communication rate for I/O type connections. Thus, a smaller or tighter pitch, P₁ (e.g., 50 μm or less) corresponds to an increased communication rate relative to a pitch of greater than 50 μm.

The inset of FIG. 1 also shows contact points 116 that, in one embodiment, have a larger diameter than contact points and a pitch, P₂, that is greater than a pitch, P₁, associated with contact points 114. In one embodiment, contact points 116 are conductive vias or pillars of an electrically conductive material (e.g., copper or nickel) having a top or superior surface available for an electrically conductive connection with die interconnect structures 110 of dies 102A and 102B. Contact points 116 are formed, in this example, on pads or traces 109 (e.g., a redistribution layer) on a surface of the substrate body under surface layer 1041. Pads or traces 109 are connected to electrically conductive vias 107 that may extend directly through package substrate 104 or to conductive traces in package substrate 104 to, for example, allow for signal transmission between dies 102A and 102B.

In one embodiment, bridge 106 may be formed according to a wafer manufacturing process. A bridge wafer is manufactured using, for example, conventional front end of line (FEOL) and back end of line (BEOL) processes to form active devices (chips). The bridge wafer may then be thinned and, after thinning, the wafer is singulated into individual bridge die which are ready for embedding in package substrate 104.

In one embodiment, package substrate 104 follows a conventional build-up process until the final build-up layer. At this point in the process, a cavity or cavities is or are introduced for a bridge (bridge 106 or bridges). A bridge is placed in a cavity, representatively held in place with an adhesive and final layers of build-up dielectrics are applied followed by fine via formation in the bridge region and coarse via formation elsewhere. The package is now ready for chip attach (e.g., die 102A and die 102B) which may be done using thermal compression bonding (TCB) followed by capillary underfill.

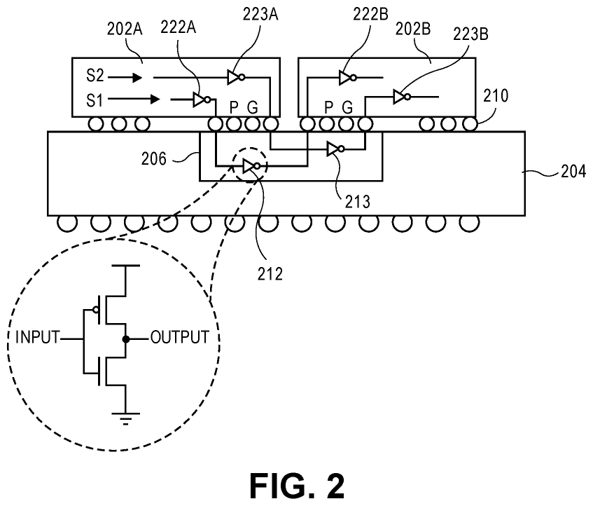

FIG. 2 shows a cross-sectional schematic side view of a package assembly including a bridge containing active device circuitry. In this embodiment, the active device circuitry includes repeaters. FIG. 2 shows package assembly including package substrate 204 including bridge 206 embedded therein. A configuration of package substrate 204 including bridge 206 may be as described above with reference to FIG. 1. Connected to a surface of package substrate 204 (a top surface as viewed) are die 202A and die 202B. Each of die 202A and die 202B may be, include, or be part of a processor, memory or ASIC. In one embodiment, each of die 202A and die 202B is a microprocessor. In one embodiment, bridge 206 serves as a communication link between dies 202A and 202B such as communication of I/O signals. In this embodiment, bridge 206 includes an active device circuitry therein in the form of repeaters. FIG. 2 schematically shows repeater 212 and repeater 213 in bridge 206. Such repeaters are, for example, inverters such as illustrated in the inset of FIG. 2. Repeaters receive a signal and retransmit the signal and may be used in this instance to reduce a delay of a transmission signal (e.g., an RC delay). In this embodiment, die 202A and die 202B also include one or more repeaters. Thus, for one signal path S1, FIG. 2 shows repeater 222A therein in die 202A. The signal path S1, travels to bridge 206 where repeater 212 is disposed in the signal path. The signal path S1, then continues to die 202B. FIG. 2 shows repeater 222B in signal path S1, in die 202B. Similarly, FIG. 2 shows signal path S2, in die 202A including repeater 223A in the signal path. Signal path S2, extends into bridge 206 which shows repeater 213 in the signal path. From repeater 213, signal path S2, proceeds to die 202B and repeater 223B. Such repeaters may be placed every half millimeter or so in signal path S1 and signal path S2. The longer distance a signal path is, a repeater will increase data rate and maintain signal integrity for longer distances and reduce a power requirement to drive the length. The use of repeaters will also reduce power supply noise. In one embodiment, signal path S1 and signal path S2 may be link matched and the repeaters can have electrostatic discharge (ESD) protection for active devices connected to the interfaces (e.g., interconnect structures 210) on both a bridge side (bridge 206) and a die side (die 202A and die 202B). In FIG. 2, a simple repeater configuration is illustrated. For multiple input and output signals, latch repeaters may be used that, for example, provide a clock signal (e.g., one forwarded clock) per a number of data bits sent. Finally, repeaters in a form of inverters may be configured as ring oscillators that will allow for testing of such active circuitry of the bridge without a tester as a frequency could be measured at a test pad on bridge 206.

FIG. 2 also shows interconnect structures 210 connecting to power and ground, in one embodiment, delivering power (P) and ground (G) to the circuits of bridge 206 from die 202A and die 202B. If die 202A and die 202B have different power supplies, in one embodiment, half the bridge can use a power supply of die 202A and the other half can use a power supply of die 202B with, for example, a level shifting inverter to cross power domains on bridge 206. If die 202A and die 202B share the same power supply, power can be shared (shorted) on bridge 206 as well.

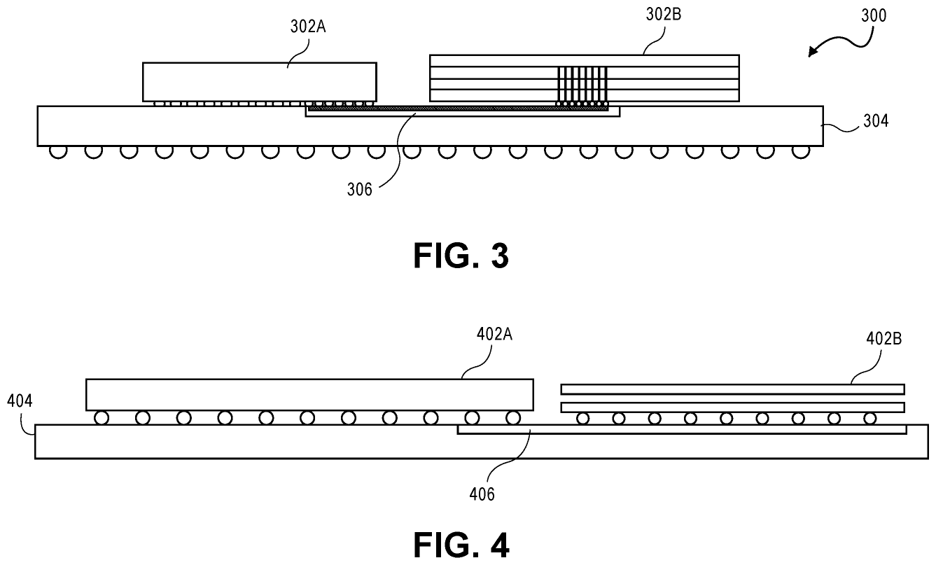

FIG. 3 shows another embodiment of a package assembly. Package assembly 300, in this embodiment, includes package substrate 304 including bridge 306 embedded therein. Bridge 306 includes active device circuitry (e.g., an active silicon bridge). Connected to a surface of package substrate 304 is die 302A and die(s) 302B. Die 302A, in one embodiment, is a microprocessor (e.g., a central processing unit (CPU)) and die(s) 302B is a memory die (e.g., dynamic random access memory (DRAM) dies (e.g., four to eight stacked DRAM dies). Generally, a controller and other protocols for a incorporating memory dies or chips into a system is located in a microprocessor. As memory standards change (e.g., High Bandwidth Memory 2 (HBM2), HBM3, wide I/O, etc.), the microprocessor must generally change or a logic chip associated with die(s) 302B. In the embodiment shown in FIG. 3, the controller and other protocols for incorporating memory dies or chips into the system (e.g., reading or writing to DRAM) is incorporated in bridge 306 rather than the microprocessor or a logic chip associated with die(s) 302B. An active bridge in a package assembly provides a relatively low cost interface for a memory chip controller (MCC) or memory control unit (MCU). As standards change, bridge 306 can be changed rather than the microprocessor. Still further, memory dies such as DRAM memory dies for use in an assembly such as a package assembly 300 may be acquired from a supplier without the supplier logic die or chip.

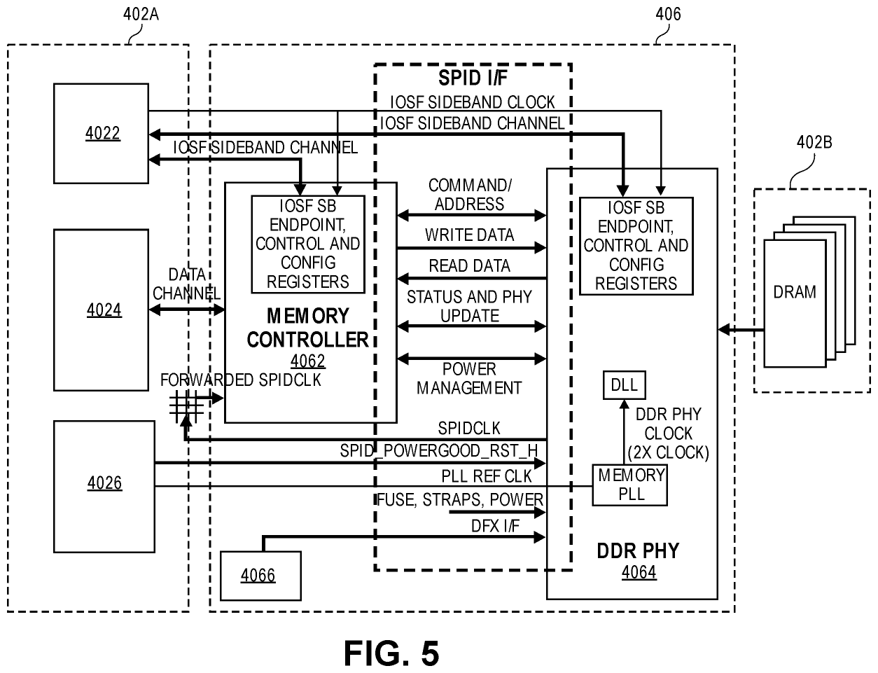

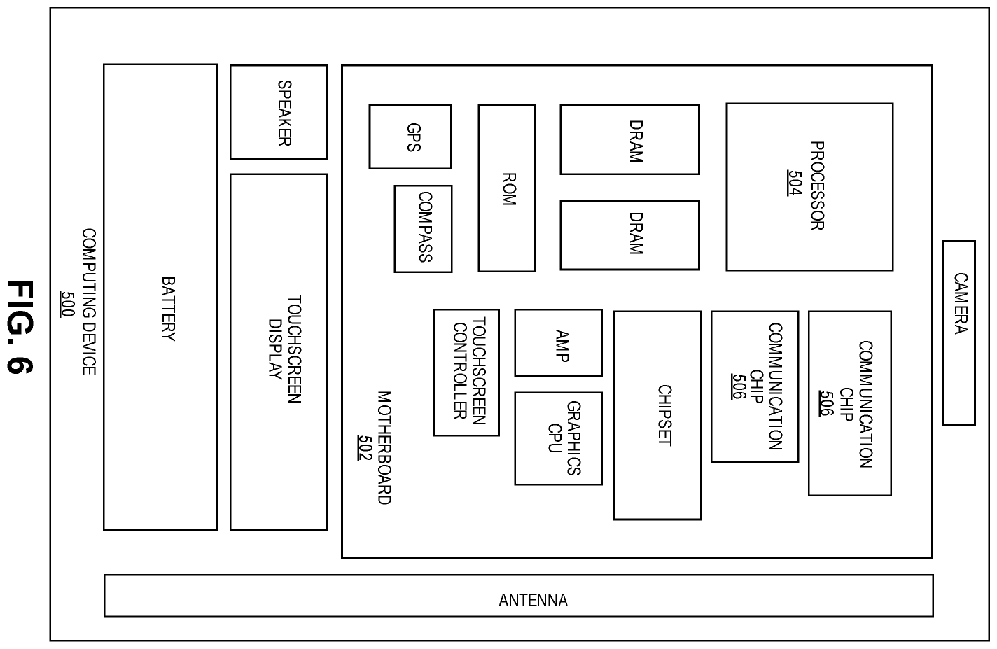

FIG. 4 shows another embodiment of a package assembly. Package assembly 400, in this embodiment, includes package substrate 404 including bridge 406 embedded therein. Bridge 406 includes active device circuitry (e.g., an active silicon bridge). Connected to a surface of package substrate 404 is die 402A and die(s) 402B. Die 402A, in one embodiment, is a central processing unit (CPU) microprocessor die and die(s) 402B is a memory die (e.g., dynamic random access memory (DRAM) dies). In this embodiment, the active circuitry of bridge 406 includes the memory controller and the interface protocol that generally defines the connectivity between the memory controller and a physical interface (PHY) for memory devices. Representatively, FIG. 5 shows a high level architecture for a double date rate (DDR) memory controller and interface (DDR PHY) incorporated in the package assembly of FIG. 4. FIG. 5 shows die 402A such as a CPU in electrical communication with memory controller 4062 in bridge 406. Representatively, CPU includes router circuitry 4022, memory traffic generation circuitry 4024 and clock/reset circuitry. Bridge 406 includes memory controller 4062 electrically connected to DDR-PHY 4064. Bridge 406 may also include test access port 4066 (e.g., Joint Test Action Group (JTAG) test access port (TAP)) connected to DDR-PHY 4064. FIG. 5 further shows die(s) 402B, such as DRAM memory dies electrically connected to bridge 406.

FIG. 6 illustrates computing device 500 in accordance with one implementation. Computing device 500 houses board 502. Board 502 may include a number of components, including but not limited to processor 504 and at least one communication chip 506. Processor 504 is physically and electrically coupled to board 502. In some implementations at least one communication chip 406 is also physically and electrically coupled to board 502. In further implementations, communication chip 506 is part of processor 504.

Depending on its applications, computing device 500 may include other components that may or may not be physically and electrically coupled to board 502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

Communication chip 506 enables wireless communications for the transfer of data to and from computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 500 may include a plurality of communication chips 506. For instance, first communication chip 506 may be dedicated to shorter range wireless communications such as Wi-Fi and Bluetooth and second communication chip 506 may be dedicated to longer range wireless communications such as GPS, EDGE, GPRS, CDMA, WiMAX, LTE, Ev-DO, and others.

Processor 504 of computing device 500 includes an integrated circuit die packaged within processor 504. In some implementations, the integrated circuit die of the processor includes one or more devices, such as transistors or metal interconnects. A package may include a package substrate such as described above with one or more embedded bridges. The term “processor” may refer to any device or portion of a device that processes electronic data from registers and/or memory to transform that electronic data into other electronic data that may be stored in registers and/or memory.

Communication chip 506 also includes an integrated circuit die packaged within communication chip 506. In accordance with another implementation, the integrated circuit die of the communication chip includes one or more devices, such as transistors or metal interconnects, that are formed in accordance with implementations.

In further implementations, another component housed within computing device 500 may contain an integrated circuit die that includes one or more devices, such as transistors or metal interconnects.

In various implementations, computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, computing device 500 may be any other electronic device that processes data.

### Examples

Example 1 is a package substrate including a substrate body including a plurality of first contact points on a surface thereof configured for electrical connection to a first die and a plurality of second contact points on the surface configured for electrical connection to a second die; and a bridge coupled to the substrate body, the bridge including active device circuitry that is coupled to ones of the plurality of first contact points and ones of the plurality of second contact points.

In Example 2, the bridge of the package substrate of Example 1 is embedded in the substrate body.

In Example 3, the active circuitry of the package substrate of Example 2 includes at least one repeater.

In Example 4, the at least one repeater of the package substrate of Example 3 is disposed in a signal path between one of the plurality of first contact points and one of the plurality of second contact points.

In Example 5, the active circuitry of the package substrate of Example 1 or 2 includes control logic.

In Example 6, the active circuitry of the package substrate of Example 1 or 2 includes a memory interface.

In Example 7, the first plurality of contact points of the package substrate of Example 1 or 2 are operable for connection to a microprocessor and the second plurality of contact points are operable for connection to at least one memory die and the active circuitry includes a memory controller.

In Example 8, the bridge of the package substrate of Example 1 or 2 includes at least one passive signal line coupled to one of the plurality of first contact points and one of the plurality of second contact points.

In Example 9, a package assembly includes the package substrate of Example 1 or 2; and a first die connected to the plurality of first contact points and a second die connected to the plurality of second contact points.

Example 10 is a package assembly including a package substrate body including a plurality of first contact points on a surface thereof configured for electrical connection to a first die and a plurality of second contact points on the surface configured for electrical connection to a second die; a bridge coupled to the substrate body, the bridge including active device circuitry that is connected to ones of the plurality of first contact points and ones of the plurality of second contact points; and a first die coupled to the plurality of first contact points and a second die connected to the plurality of second contact points.

In Example 11, the bridge of the package assembly of Example 10 is embedded in the substrate body.

In Example 12, the active device circuitry of the package assembly of Example 11 is configured to route input/output electrical signals.

In Example 13, the active circuitry of the package assembly of Example 10 or 11 includes at least one repeater.

In Example 14, the at least one repeater of the package assembly of Example 13 is disposed in a signal path between one of the plurality of first contact points and one of the plurality of second contact points.

In Example 15, the active circuitry of the package assembly of Example 10 or 11 includes control logic or a memory circuit.

In Example 16, the active circuitry of the package assembly of Example 11 includes a memory circuit.

In Example 17, the first die of the package assembly of Example 10 is a microprocessor and the second die is a microprocessor.

In Example 18, the first die of the package assembly of Example 11 is a microprocessor and the second die is at least one memory die and the active circuitry includes a memory controller.

In Example 19, the bridge of the package assembly of Example 11 includes at least one passive signal line coupled to one of the plurality of first contact points and one of the plurality of second contact points.

Example 20 is a method of forming a package assembly including connecting a first die to a package substrate, the package substrate including a bridge substrate including active device circuitry; and connecting a second die to the package substrate, wherein connecting the first die and the second die to the package substrate includes connecting the first die and the second die to the active circuitry.

In Example 21, the active device circuitry in the method of Example 20 includes a repeater.

In Example 22, the first die in the method of Example 20 is a microprocessor and the second die is at least one memory die and the active circuitry includes a memory controller.

In Example 23, the first die in the method of Example 19 is a microprocessor and the second die is a microprocessor.

The above description of illustrated implementations, including what is described in the Abstract, is not intended to be exhaustive or to limit the invention to the precise forms disclosed. While specific implementations of, and examples for, the invention are described herein for illustrative purposes, various equivalent modifications are possible within the scope, as those skilled in the relevant art will recognize.

These modifications may be made to the invention in light of the above detailed description. The terms used in the following claims should not be construed to limit the invention to the specific implementations disclosed in the specification and the claims. Rather, the scope is to be determined entirely by the following claims, which are to be construed in accordance with established doctrines of claim interpretation.

1. A package substrate comprising:
a substrate body comprising a plurality of first contact points on a surface thereof configured for electrical connection to a first die and a plurality of second contact points on the surface configured for electrical connection to a second die; and
a bridge coupled to the substrate body, the bridge comprising active device circuitry that is coupled to ones of the plurality of first contact points and ones of the plurality of second contact points.

2. The package substrate of claim 1, wherein the bridge is embedded in the substrate body.

3. The package substrate of claim 2, wherein the active circuitry comprises at least one repeater.

4. The package substrate of claim 3, wherein the at least one repeater is disposed in a signal path between one of the plurality of first contact points and one of the plurality of second contact points.

5. The package substrate of claim 2, wherein the active circuitry comprises control logic.

6. The package substrate of claim 2, wherein the active circuitry comprises a memory interface.

7. The package substrate of claim 2, wherein the first plurality of contact points are operable for connection to a microprocessor and the second plurality of contact points are operable for connection to at least one memory die and the active circuitry comprises a memory controller.

8. The package substrate of claim 2, wherein the bridge comprises at least one passive signal line coupled to one of the plurality of first contact points and one of the plurality of second contact points.

9. A package assembly comprising:
a package substrate body comprising a plurality of first contact points on a surface thereof configured for electrical connection to a first die and a plurality of second contact points on the surface configured for electrical connection to a second die;
a bridge coupled to the substrate body, the bridge comprising active device circuitry that is coupled to ones of the plurality of first contact points and ones of the plurality of second contact points; and
a first die coupled to the plurality of first contact points and a second die coupled to the plurality of second contact points.

10. The package assembly of claim 9, wherein the bridge is embedded in the substrate body.

11. The package assembly of claim 10, wherein the active device circuitry is configured to route input/output electrical signals.

12. The package assembly of claim 10, wherein the active circuitry comprises at least one repeater.

13. The package assembly of claim 12, wherein the at least one repeater is disposed in a signal path between one of the plurality of first contact points and one of the plurality of second contact points.

14. The package assembly of claim 10, wherein the active circuitry comprises control logic.

15. The package assembly of claim 10, wherein the active circuitry comprises a memory circuit.

16. The package assembly of claim 10, wherein the first die is a microprocessor and the second die is at least one memory die and the active circuitry comprises a memory controller.

17. The package assembly of claim 10, wherein the first die is a microprocessor and the second die is a microprocessor.

18. The package assembly of claim 10, wherein the bridge comprises at least one passive signal line coupled to one of the plurality of first contact points and one of the plurality of second contact points.

19. A method of forming a package assembly comprising:
coupling a first die to a package substrate, the package substrate comprising a bridge substrate comprising active device circuitry; and
coupling a second die to the package substrate,
wherein coupling the first die and the second die to the package substrate comprises coupling the first die and the second die to the active circuitry.

20. The method of claim 19, wherein the active device circuitry comprises a repeater.

21. The method of claim 19, wherein the first die is a microprocessor and the second die is at least one memory die and the active circuitry comprises a memory controller.

22. The method of claim 19, wherein the first die is a microprocessor and the second die is a microprocessor.

23. The package substrate of claim 1, wherein the bridge comprises at least one of a transistor or a memory element.

24. The package substrate of claim 1, wherein the bridge comprises one or more through silicon vias (TSVs).

25. The package substrate of claim 1, wherein the bridge comprises a DRAM controller.

26. The package substrate of claim 1, wherein the bridge comprises a semiconductor material.

27. The package assembly of claim 9, wherein the bridge comprises at least one of a transistor or a memory element.

28. The package assembly of claim 9, wherein the bridge comprises one or more through silicon vias (TSVs).

29. The package assembly of claim 9, wherein the bridge comprises a DRAM controller.

30. The package assembly of claim 9, wherein the bridge comprises a semiconductor material.

31. The method of claim 19, further comprising:
forming at least one of a transistor or a memory element in the bridge substrate.

32. The method of claim 19, further comprising:
forming one or more through silicon vias (TSVs) in the bridge substrate.

33. The method of claim 19, further comprising:
forming a DRAM controller in the bridge substrate.

34. The method of claim 19, wherein the bridge substrate comprises a semiconductor material.
